(19) United States
(12) Patent Application Publication
(10) Pub. No.: US 2008/0048736 A1
(43) Pub. Date: Feb. 28, 2008

(54) Differential circuit and output buffer circuit including the same

(75) Inventor: Jong-Jae Ruy, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/879,631

(22) Filed: Jul. 18, 2007

(30) Foreign Application Priority Data
Jul. 24, 2006 (KR) 10-2006-0068839

(51) Int. Cl. H03B 1/00

(52) U.S. Cl. 327/108

(57) ABSTRACT

An output buffer circuit in a multi-power system operating at a high power supply voltage and a low power supply voltage includes a pre-driver, and a main driver. The pre-driver performs a differential switching operation on first and second differential input signals to output first and second differential output signals. The main driver performs a differential switching operation on the DC-eliminated and level-shifted first and second differential output signals to output third and fourth differential output signals. The main driver includes a differential switching circuit including first and second NMOS transistors, and performs a differential switching operation on the DC-eliminated and level-shifted first and second differential output signals to output the third and fourth differential output signals, and an equalizer coupled between source electrodes of the first and second NMOS transistors, and controls a bandwidth of the third and fourth differential output signals.

### CROSS-REFERENCE TO RELATED APPLICATIONS

This application claims priority under 35 USC § 119 to Korean Patent Application No. 10-2006-0068839, filed on Jul. 24, 2006 in the Korean Intellectual Property Office (KIPO), the disclosure of which is incorporated herein in its entirety by reference.

### BACKGROUND OF THE INVENTION

1. Field of the Invention

The present invention relates to a power supply in a semiconductor memory device, and more particularly to a differential circuit and an output buffer including the differential circuit.

2. Description of the Related Art

A power supply voltage used in a complementary metal-oxide semiconductor (CMOS) circuit has been decreasing according to the development of CMOS technology. Accordingly, it is more difficult to provide a high output voltage at an output buffer using a conventional CMOS circuit.

FIG. 1 is a circuit diagram illustrating a conventional output buffer employing a transistor having a low-voltage gate oxide.

Referring to FIG. 1, the conventional output buffer circuit includes loads R11 and R12 coupled to a low power supply voltage VDDL, for example, about 1.2 volts, NMOS transistors NT11 and NT12 that function as a differential switching circuit, and an NMOS transistor NT13 that functions as a constant current source operating in response to a bias voltage Vc.

The output buffer circuit of FIG. 1 provides a low-voltage output signal using the low power supply voltage VDDL.

Particularly, the output buffer circuit of FIG. 1 receives two differential input voltages VIn+ and VIn− that swing between a first voltage level and a second voltage level, and provides differential output voltages VOut+ and VOut− that swing between a third voltage level and a fourth voltage level using the low power supply voltage VDDL.

The transistors NT11 and NT12, respectively, are implemented with a low-voltage gate oxide transistor. The low-voltage gate oxide transistor includes a gate dielectric layer (for example, a gate oxide) having a thickness that can endure a voltage level of the low power supply voltage VDDL. The low-voltage gate oxide transistor can have a gate oxide that is relatively thin compared with the thickness of the high-voltage gate oxide transistor.

A body, i.e., a p-substrate, of the NMOS transistors NT11 and NT12 is coupled to a bias voltage of a ground level. Thus, a maximum voltage difference between a gate and a body of each of the transistors NT11 and NT12 is the low power voltage VDDL.

In the conventional output buffer circuit of FIG. 1, the NMOS transistors NT11 and NT12 are implemented with a low-voltage gate oxide NMOS transistor, and a high power supply voltage VDDH is coupled to the loads R11 and R12 so as to output a high-voltage output signal. Thus, a voltage difference between the gate and the body of each of the transistors NT11 and NT12 can be larger than the maximum allowable voltage of 1.2 volts of the low-voltage gate oxide NMOS transistor, and thus reliability of the thin gate oxide can be deteriorated.

Accordingly, since the reliability of the output buffer of FIG. 1 is deteriorated if a low-voltage NMOS transistor of a thin gate oxide is used in order to achieve a high operation speed and simultaneously in order to obtain a high-voltage output signal by increasing a voltage level of the power supply voltage, the output buffer has to be implemented with a thick gate oxide transistor, i.e., a high-voltage transistor, as the differential switching transistor.

FIG. 2 is a circuit diagram illustrating a conventional output buffer circuit employing a transistor having a high-voltage gate oxide.

Referring to FIG. 2, the output buffer circuit includes loads R21 and R22 coupled to a high power supply voltage VDDH, NMOS transistors NT21 and NT22 that function as a differential switching circuit, and an NMOS transistor NT23 that functions as a constant current source.

The output buffer circuit of FIG. 2 provides a high-voltage output signal using the high power supply voltage VDDH.

Particularly, the output buffer circuit of FIG. 2 receives two differential input voltages VIn+ and VIn−, and provides differential output voltages VOut+ and VOut− using the high power supply voltage VDDH, of which a maximum voltage level is substantially the same as a level of the high power supply voltage VDDH.

The transistors NT21 and NT22 are implemented with a high-voltage gate oxide transistor that includes a gate oxide having a thickness sufficient to enable the gate oxide to endure a voltage level of the high power supply voltage VDDH. Bodies of the NMOS transistors NT21 and NT22 are coupled to a bias voltage of a ground level. Thus, a maximum voltage difference between a gate and a body of each of the transistors NT11 and NT12 is the high power supply voltage VDDH.

The thick gate oxide transistor cannot provide high operational speed due to relatively low driving capacity, compared with the thin gate oxide transistor.

When the NMOS transistors NT21 and NT22 employ a low-voltage gate oxide NMOS transistor in an output buffer circuit that operates at the high power supply voltage VDDH, the maximum voltage difference between the gate and the body of each of the transistors NT11 and NT12 can be the high power supply voltage VDDH.

However, the reliability of the low-voltage gate oxide transistor can be deteriorated due to a bias voltage higher than the maximum allowable voltage of the low-voltage gate oxide transistor. Thus, it is difficult to employ the low-voltage gate oxide transistor in an output buffer circuit that operates at a high power supply voltage. Therefore, the conventional output buffer circuit that operates at the high power supply voltage so as to obtain the high-voltage output signal cannot provide the high operational reliability and the high operational speed at the same time. That is, the conventional output buffer circuit that operates at the high power supply voltage cannot simultaneously provide both the high operational speed and the high-voltage output signal.

### SUMMARY OF THE INVENTION

In accordance various aspects of the present invention, provided is a differential circuit operating at a high power supply voltage that can output differential signals of high voltage level.

In accordance with other aspects of the present invention, provided is an output buffer operating at a high power supply voltage and a low power supply voltage that can output differential signals of high voltage level at very high speed.

In one aspect of the present invention, provided is a differential circuit configured to operate at a high power supply voltage that includes a differential switching circuit and an equalizer. The differential switching circuit includes first and second n-type metal-oxide semiconductor (NMOS) transistors, and is configured to perform a differential switching operation on first and second differential input signals to output first and second differential output signals, each of the first and second NMOS transistors being a high-voltage NMOS transistor. The equalizer is coupled between source electrodes of the first and second NMOS transistors, and is configured to control a bandwidth of the first and second differential output signals.

The differential circuit can be employed in a multi-power system configured to operate at the high power supply voltage and the low power supply voltage.

The differential circuit can further include a current source circuit coupled between the source electrodes of the first and second NMOS transistors.

The current source circuit can include at least one low-voltage NMOS transistor.

The current source circuit can be configured to operate in a saturation region in response to a bias voltage applied to a gate of the at least one low-voltage NMOS transistor.

The equalizer can include a bandwidth control unit coupled between the source electrodes of the first and second NMOS transistors, and an equalizer control unit coupled between the source electrodes of the first and second NMOS transistors. The equalizer control unit can be configured to control electrical connection between the source electrodes of the first and second NMOS transistors in response to an equalizer control signal.

The bandwidth control unit can include a variable capacitor and a variable resistor that are coupled in parallel with respect to each other, and a capacitance of the variable capacitor and a resistance of the variable resistor can be determined in response to a bandwidth control signal.

The equalizer control unit can include a third NMOS transistor having a gate configured to receive the equalizer control signal.

The third NMOS transistor can be a low-voltage NMOS transistor.

The third NMOS transistor can be configured to operate in a saturation region in response to the equalizer control signal applied to the gate of the third NMOS transistor.

The differential circuit can further include a load unit coupled between the high supply voltage and the differential switching circuit.

The load unit can include a first load circuit coupled between the high supply voltage and a drain electrode of the first NMOS transistor, and a second load circuit coupled between the high supply voltage and a drain electrode of the second NMOS transistor.

In accordance with another aspect of the present invention, provided is a differential circuit that includes a first load coupled to a high power supply voltage, a second load coupled to the high power supply voltage, a first NMOS transistor having a high-voltage gate oxide layer, the first NMOS transistor having a gate electrode configured to receive a first input signal and a drain electrode coupled to one terminal of the first load, a second NMOS transistor having a high-voltage gate oxide layer, the second NMOS transistor having a gate electrode configured to receive a second input signal is applied and a drain electrode coupled to one terminal of the second load, the first and second input signals constituting a differential signal, an equalizer, and a switching circuit coupled between the source electrodes of the first and second NMOS transistors in parallel with respect to the variable resistor. The equalizer includes a variable capacitor coupled between source electrodes of the first and second NMOS transistors, and a variable resistor coupled between the source electrodes of the first and second NMOS transistors and in parallel with the variable capacitor.

The differential circuit can further include a current source coupled between the equalizer and a ground voltage.

The differential circuit can be employed in a multi-power system and is configured to operate at the high power supply voltage and the low power supply voltage.

In accordance with another aspect of the present invention, provided is an output buffer circuit in a multi-power system configured to operate operate at a high power supply voltage and a low power supply voltage. The output buffer circuit includes a pre-driver, a blocking capacitor unit, a voltage reference circuit, and a main driver. The pre-driver is configured to perform a differential switching operation on first and second differential input signals to output first and second differential output signals. The blocking capacitor unit includes a first blocking capacitor configured to eliminate a DC component of the first differential output signal and a second blocking capacitor configured to eliminate a DC component of the second differential output signal. A first terminal of the first blocking capacitor is coupled to a first output terminal of the pre-driver. A second terminal of the second blocking capacitor is coupled to a second output terminal of the pre-driver. The voltage reference circuit is coupled to a second terminal of the first blocking capacitor and a second terminal of a second blocking capacitor, and is configured to shift voltage levels of the DC-eliminated first and second differential output signals. The main driver is configured to perform a differential switching operation on the DC-eliminated and level-shifted first and second differential output signals to output third and fourth differential output signals. The main driver includes a differential switching circuit including first and second NMOS transistors, and is configured to perform a differential switching operation on the DC-eliminated and level-shifted first and second differential output signals to output the third and fourth differential output signals, and an equalizer coupled between source electrodes of the first and second NMOS transistors, and configured to control a bandwidth of the third and fourth differential output signals.

The first and second NMOS transistors can be high-voltage NMOS transistors.

The output buffer can further comprise a current source circuit coupled between the source electrodes of the first and second NMOS transistors.

The equalizer can include a bandwidth control unit coupled between the source electrodes of the first and second NMOS transistors, and an equalizer control unit coupled between the source electrodes of the first and second NMOS transistors, and configured to control electrical connection between the source electrodes of the first and second NMOS transistors in response to an equalizer control signal.

The output buffer circuit can further include load circuit coupled between the high power supply voltage and the differential circuit.

The pre-driver can include a pre-stage differential switching circuit including third and fourth NMOS transistors, and configured to perform a differential switching operation on the first and second differential input signals to output first and second differential output signals. Each of the third and fourth NMOS transistors can be a low-voltage NMOS transistor.

Each source electrode of the third and fourth NMOS transistors can be coupled at a common source node.

The pre-driver can further include a pre-stage current source circuit coupled between the common source node and a ground voltage.

The pre-stage current source circuit can include at least one NMOS transistor having a low-voltage gate oxide layer.

The pre-stage current source circuit can be configured to operate in a saturation region in response to a bias voltage applied to a gate of the at least one NMOS transistor having the low-voltage gate oxide layer.

The pre-driver can further include pre-stage load unit coupled between the low power supply voltage and the pre-differential switching circuit.

The pre-stage load unit can include a first pre-stage load circuit coupled between the low power supply voltage and a drain electrode of the third NMOS transistor, and a second pre-stage load circuit coupled between the low power supply voltage and a drain electrode of the fourth NMOS transistor.

Therefore, the output buffer circuit is capable of providing simultaneously both of the high operational speed and the high-voltage output signal.

### BRIEF DESCRIPTION OF THE DRAWINGS

FIG. 1 is a circuit diagram illustrating a conventional output buffer employing a transistor having a low-voltage gate oxide.

FIG. 2 is a circuit diagram illustrating a conventional output buffer circuit employing a transistor having a high-voltage gate oxide.

FIG. 3 is a circuit diagram illustrating an embodiment of a differential circuit employing a transistor having a high-voltage gate oxide according to an aspect of the present invention.

FIG. 4 is a block diagram illustrating an embodiment of an output buffer circuit of a multi-power system according to an aspect of the present invention.

FIG. 5 is an embodiment of a circuit diagram illustrating a pre-driver in the output buffer circuit of FIG. 4.

FIG. 6 is a circuit diagram illustrating an embodiment of a main driver in the output buffer circuit of FIG. 4.

FIG. 7 is a diagram illustrating levels of the high power supply voltage VDDH and the low power supply voltage VDDL that are applied to the differential circuit of FIG. 3 and the output buffer circuit of FIGS. 4 to 6.

FIG. 8 is a simulation diagram illustrating an output waveform of the output buffer operating at 4.25 Gbps when the low power supply voltage VDDL of FIG. 7 is applied to the pre-driver of FIG. 5 and main driver of FIG. 6.

FIGS. 9A and 9B are simulation diagrams illustrating output waveforms of the output buffer operating at 4.25 Gbps when the low power supply voltage VDDL of FIG. 7 is applied to the pre-driver of FIG. 5 and the high power supply voltage VDDH of FIG. 7 is applied to the main driver of FIG. 6.

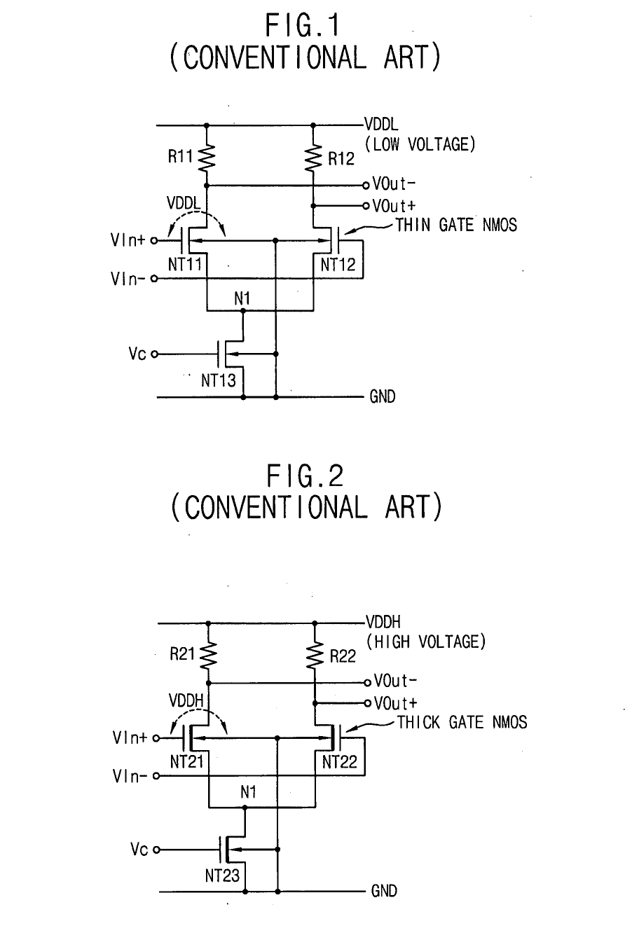

### DESCRIPTION OF THE EMBODIMENTS

Embodiments of the present invention now will be described more fully with reference to the accompanying drawings, in which embodiments of the invention are shown. The present invention can, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout this application.

It will be understood that, although the terms first, second, etc. can be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

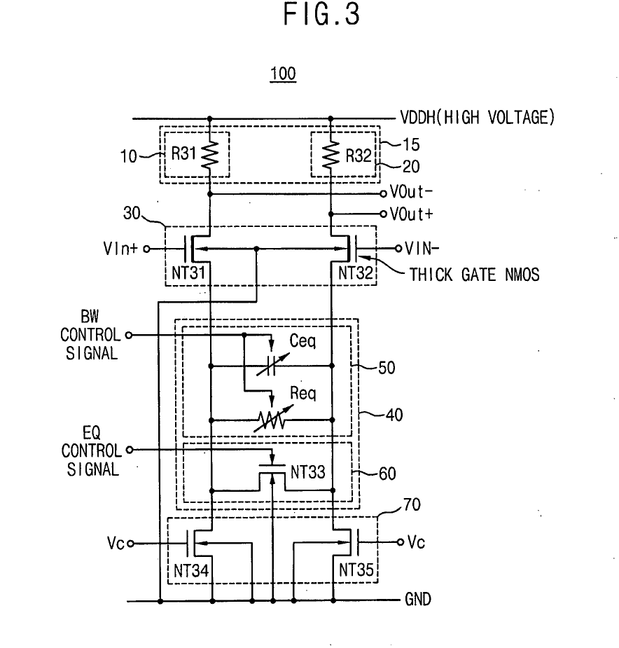

FIG. 3 is a circuit diagram illustrating an example embodiment of a differential circuit employing a transistor having a high-voltage gate oxide according to aspects of the present invention. Such a differential circuit can be employed in a multi-power system that uses a high power supply voltage and a low power supply voltage.

Referring to FIG. 3, the differential circuit 100 includes a load unit 15 comprising a first load circuit 10 and a second load circuit 20 coupled to a high power supply voltage VDDH, a differential switching circuit 30, an equalizer 40, and a current source 70.

The first and second load circuits 10 and 20 can be implemented with a resistor. For example, the first load circuit 10 includes a resistor R31, and the second load circuit 20 includes a resistor R32, in this embodiment. The first and second load circuits 10 and 20 can be implemented with other circuit elements, such as transistors, etc, which can function as a load.

The differential switching circuit 30 can include N-type metal-oxide semiconductor (NMOS) transistors NT31 and NT32. The NMOS transistor NT31 receives a first differential input signal VIn+, and the NMOS transistor NT32 receives a second differential input signal VIn−. The differential switching circuit 30 can be implemented with more than two NMOS transistors that receive the first differential input signal VIn+, and more than two NMOS transistors that receive the second differential input signal VIn−.

The NMOS transistors NT31 and NT32 employ a thick gate oxide that can endure a voltage level of the high power supply voltage VDDH.

The equalizer 40 includes a bandwidth control unit 50 and an equalizer control unit 60.

The bandwidth control unit 50 includes a variable capacitor Ceq and a variable resistor Req that are coupled in parallel to each other between source electrodes of the NMOS transistors NT31 and NT32. The bandwidth control unit 50 controls a bandwidth of first and second differential output signals VOut+ and VOut− in response to a bandwidth control signal from a controller (not illustrated). The variable capacitor Ceq can include a plurality of capacitors that are coupled in parallel, and provide a capacitance in response to a control signal. The variable resistor Req can include a plurality of resistors that are coupled in series, and provide a resistance in response to a control signal.

The equalizer control unit 60 can include an NMOS transistor NT33 that is coupled between the source electrodes of the NMOS transistors NT31 and NT32. The NMOS transistor NT33 is turned on/off in response to an equalizer control signal applied to a gate of the NMOS transistor NT33 from the controller (not illustrated). Two terminals of the NMOS transistor NT33 are short-circuited or opened when the NMOS transistor NT33 is turned on or turned off, and thus the bandwidth control unit 50 affects or does not affect on the differential switching circuit 30. The NMOS transistor NT33 can employ a thin gate oxide.

The current source 70 can include NMOS transistors NT34 and NT35, which can be low-voltage NMOS transistors. The transistors NT34 and NT35 have gates that are coupled to a bias voltage Vc, and operate in a saturation region. A magnitude of the constant current provided by the transistors NT34 and NT35 can be determined by the bias voltage Vc. The current source 70 can be implemented with any other circuit element that functions as a current source. For example, the current source 70 can be replaced by a load circuit including a resistor. Bodies of the NMOS transistors in FIG. 3 are coupled to the ground voltage GND.

The differential circuit of FIG. 3 receives the first and second differential input signals VIn+ and VIn− that swing between a first voltage level and a second voltage level via gates of the transistors NT31 and NT32, performs a differential switching on the first and second differential input signals VIn+ and VIn−, and provides the first and second differential output signals VOut+ and VOut− that swing between a third voltage level and a fourth voltage level to drains of the transistors NT31 and NT32. That is, the differential circuit of FIG. 3 operates at the high power supply voltage VDDH as a power source to provide a high-voltage output signal.

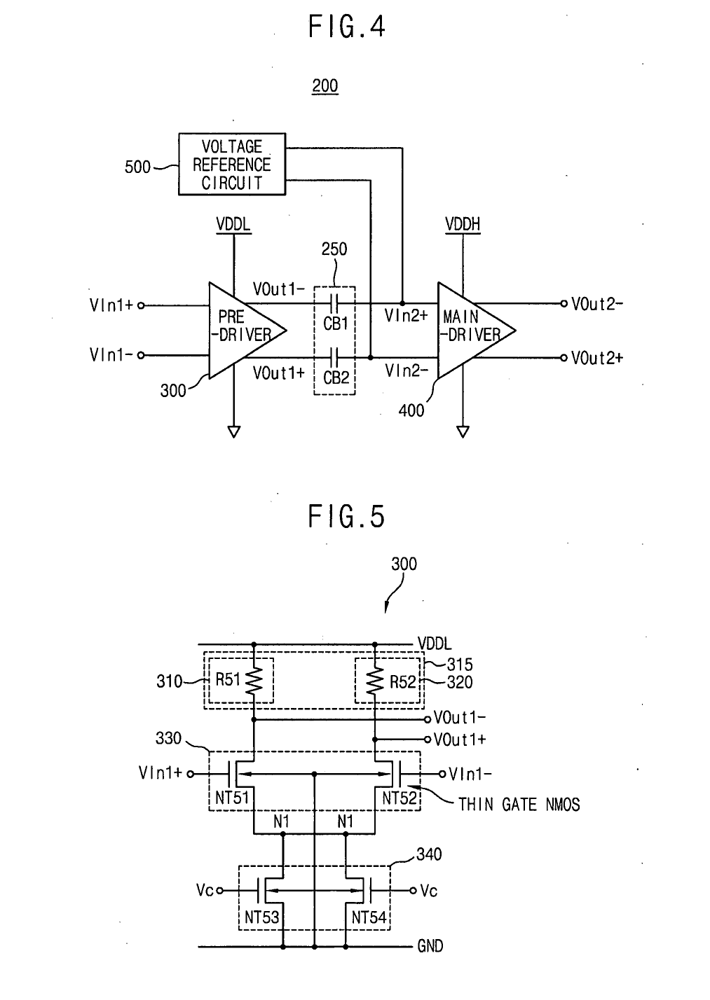

FIG. 4 is a block diagram illustrating an example embodiment of an output buffer circuit of a multi-power system according to an aspect of the present invention.

Referring to FIG. 4, the output buffer circuit 200 includes a pre-driver 300 and a main driver 400. The output buffer circuit 200 can further include a blocking capacitor unit 250 comprising a first blocking capacitor CB1 and a second blocking capacitor CB2 between the pre-driver 300 and the main driver 400 for blocking DC components. In addition, the output buffer circuit 200 can further include a voltage reference circuit 500 between the pre-driver 300 and the main driver 400 for shifting a voltage level.

FIG. 5 is a circuit diagram illustrating an embodiment of a pre-driver in the output buffer circuit of FIG. 4.

Referring to FIG. 5, the pre-driver 300 includes a pre-stage load unit 315 that comprises a first pre-stage load circuit 310, a second pre-stage load circuit 320, which are coupled to a low power supply voltage VDDL, a pre-stage differential switching circuit 330, and a pre-stage current source 340.

The first and second pre-stage load circuits 310 and 320 can be implemented with resistors R51 and R52, respectively.

While the example embodiments and their advantages have been described in detail, it should be understood that various changes, substitutions and alterations can be made herein without departing from the scope of the invention. For example, the first and second pre-stage load circuits 310 and 320 can be implemented with other circuit elements, such as transistors, etc, that function as a load.

The pre-stage differential switching circuit 330 can include NMOS transistors NT51 and NT52. The NMOS transistor NT51 receives a first differential input signal VIn+, and the NMOS transistor NT52 receives a second differential input signal VIn−. The differential switching circuit 330 can be implemented with more than two NMOS transistors that receive the first differential input signal VIn+, and more than two NMOS transistors that receive the second differential input signal VIn−.

The NMOS transistors NT51 and NT52 employ a thin gate oxide that can endure a voltage level of the low power supply voltage VDDL.

The pre-stage current source 340 can include NMOS transistors NT53 and NT54, wherein the source of each of NMOS transistors NT53 and NT54 is coupled together at a common source node N1. The transistors NT53 and NT54 can employ a thin gate oxide. The transistors NT53 and NT54 have gates that are coupled to a bias voltage Vc, and operate in a saturation region. A magnitude of the constant current provided by the transistors NT53 and NT54 can be determined by the bias voltage Vc. The pre-stage current source 340 can be implemented with any other circuit element that functions as a current source. For example, the pre-stage current source 340 can be replaced by a load circuit including a resistor.

The pre-driver 300 receives first and second differential input signals Vin1+ and Vin1− that swing between a first voltage level and a second voltage level via gates of the transistors NT51 and NT52, performs a differential switching on the first and second differential input signals Vin1+ and Vin1−, and provides first and second differential output signals VOut1+ and VOut1− that swing between a third voltage level and a fourth voltage level to drains of the transistors NT51 and NT52. That is, the pre-driver of FIG. 5 operates at the low power supply voltage VDDL as a power supply voltage to provide a low-voltage output signal at a relatively high speed.

The first blocking capacitor CB1 and the second blocking capacitor CB2 eliminate the DC components of the first and second differential output signals VOut1+ and VOut1−, respectively. Voltage levels of the DC-eliminated first and second differential output signals VOut1+ and VOu1− are not enough for driving transistors of the main driver 400, since the transistors employ a thick gate oxide. Accordingly, the voltage reference circuit 500 between the pre-driver 300 and the main driver 400 shifts the voltage levels of the DC-eliminated first and second differential output signals VOut1+ and VOut1− to levels sufficient for driving transistors that employ the thick gate oxide of the main driver 400.

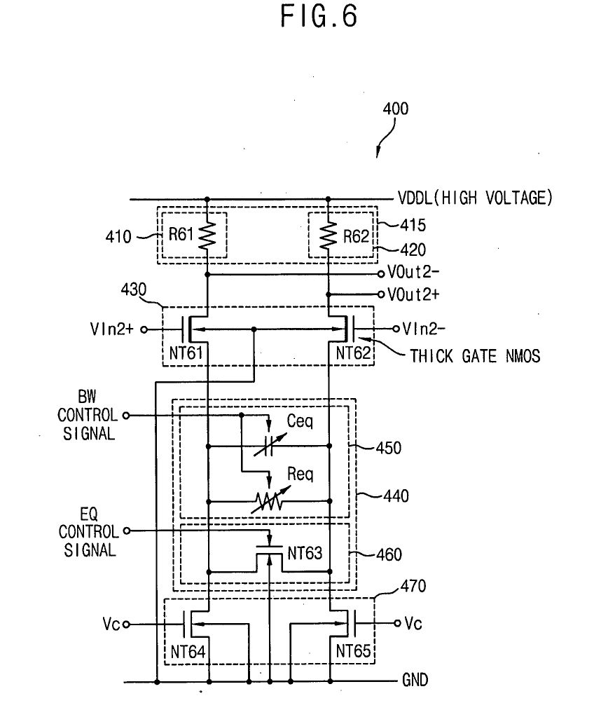

FIG. 6 is a circuit diagram illustrating an embodiment of a main driver in the output buffer circuit of FIG. 4.

Referring to FIG. 6, the main driver 400 includes a load circuit 415 that comprises a first load circuit 410 and a second load circuit 420 coupled to a high power supply voltage VDDH, a differential switching circuit 430, an equalizer 440, and a current source 470.

The first and second load circuits 410 and 420 can be implemented with a resistor. For example, the first load circuit 410 includes a resistor R61, and the second load circuit 420 includes a resistor R62.

The differential switching circuit 430 includes NMOS transistors NT61 and NT62 that employ a thick gate oxide.

The equalizer 440 includes a bandwidth control unit 450 and an equalizer control unit 460. The bandwidth control unit 450 includes a variable capacitor Ceq and a variable resistor Req, and receives a bandwidth control signal. The equalizer control unit 450 receives an equalizer control signal.

The current source 470 includes NMOS transistors NT64 and NT65 that employ a thin gate oxide.

Operation of the main driver 400 of FIG. 6 is substantially similar to operation of the differential circuit 100 of FIG. 3.

The main driver 400 receives first and second DC-eliminated and level-shifted output signals VIn2+ and VIn2− via gates of the transistors NT61 and NT62, performs a differential switching on the first and second output signals VIn2+ and VIn2− that are DC-eliminated and level-shifted, and provides third and fourth output signals VOut2+ and VOut2− that have a high voltage level.

The equalizer 440 of the main driver 400 is capable of solving signal distortions due to an additional circuit load caused by the DC elimination and the level shifting, and due to a parasitic capacitance caused by the transistors employing the thick gate oxide of main driver 400. That is, a bandwidth of the third and fourth output signals VOut2+ and VOut2− can be controlled according to an application and a circuit characteristic by controlling the variable capacitor Ceq and the variable resistor Req based on the bandwidth control signal.

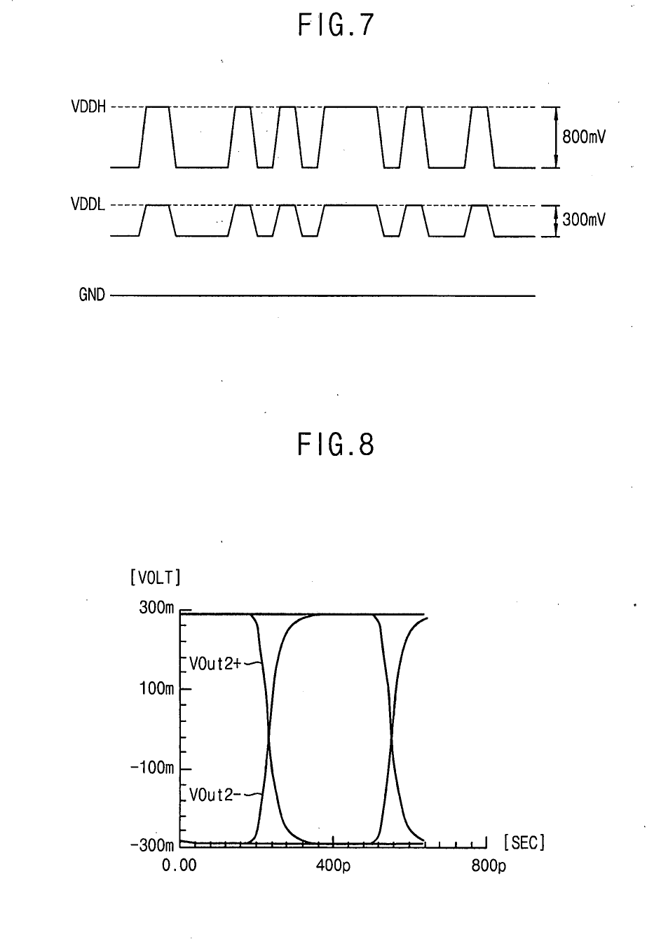

FIG. 7 is a diagram illustrating levels of the high power supply voltage VDDH and the low power supply voltage VDDL that are applied to the differential circuit 100 of FIG. 3 and the output buffer circuit 200 of FIGS. 4, 5 and 6.

FIG. 8 is a simulation diagram illustrating an output waveform of the output buffer, i.e., of VOut2+ and VOut2−, operating at 4.25 Gbps when the low power supply voltage VDDL of FIG. 7 is applied to the pre-driver of FIG. 5 and main driver of FIG. 6.

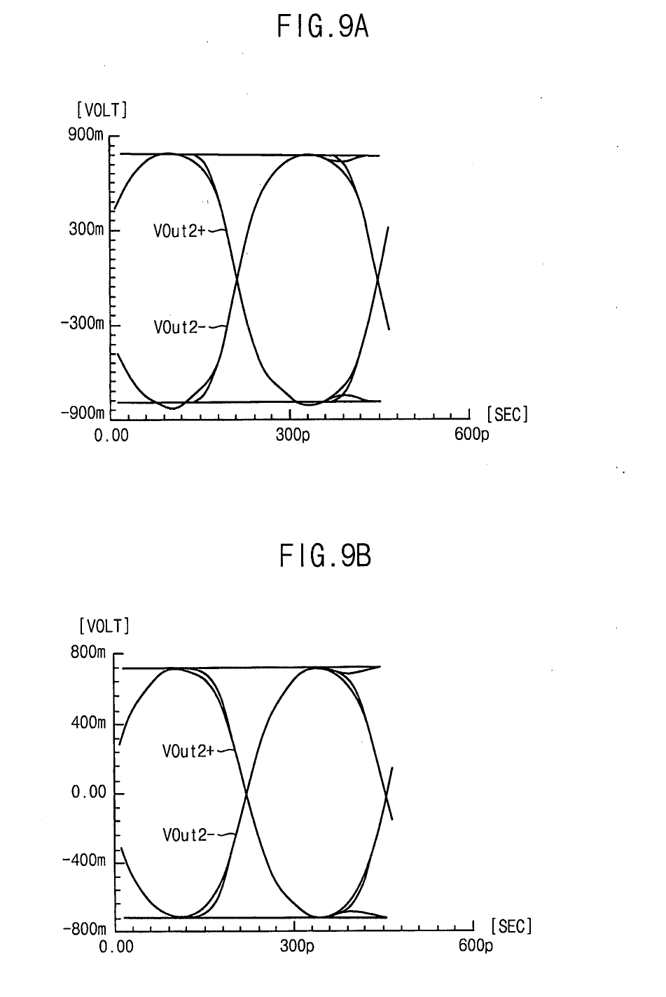

FIGS. 9A and 9B are simulation diagrams illustrating output waveforms of the output buffer, i.e., of VOut2+ and VOut2−, operating at 4.25 Gbps when the low power supply voltage VDDL of FIG. 7 is applied to the pre-driver of FIG. 5 and the high power supply voltage VDDH of FIG. 7 is applied to the main driver of FIG. 6.

Referring to FIG. 8, the output waveform of FIG. 8 has peak-to-peak voltage level of about 600 mV, and half-period driving time of about 400 psec. However, referring to FIGS. 9A and 9B, the output waveform of the output buffer circuit of according to this an example embodiment has peak-to-peak voltage level of about 1600 mV, and half-period driving time of about 200 psec. Accordingly, the output buffer circuit is capable of outputting high-level signals at a relatively high speed.

As mentioned above, the differential circuit and the output buffer circuit including the differential circuit according to this disclosure can be employed in a multi-power system operating at a high power supply voltage and a low power supply voltage. The pre-driver includes a differential circuit that employs low-voltage NMOS transistors, and the main driver includes a differential circuit that employs high-voltage NMOS transistors. Accordingly, the output buffer circuit is capable of providing simultaneously both operational speed and the high-voltage output signal.

While the example embodiments in accordance with aspects of the present invention and their advantages have been described in detail, it should be understood that various changes, substitutions and alterations can be made herein without departing from the scope of the invention. It is intended by the following claims to claim that which is literally described and all equivalents thereto, including all modifications and variations that fall within the scope of each claim.

What is claimed is:

1. A differential circuit configured to operate at a high power supply voltage, the differential circuit comprising:
a differential switching circuit including first and second n-type metal-oxide semiconductor (NMOS) transistors, and configured to perform a differential switching operation on first and second differential input signals to output first and second differential output signals, each of the first and second NMOS transistors being a high-voltage NMOS transistor; and
an equalizer coupled between source electrodes of the first and second NMOS transistors, and configured to control a bandwidth of the first and second differential output signals.

2. The differential circuit of claim 1, wherein the differential circuit is employed in a multi-power system configured to operate at the high power supply voltage and the low power supply voltage.

3. The differential circuit of claim 2, further comprising a current source circuit coupled between the source electrodes of the first and second NMOS transistors.

4. The differential circuit of claim 3, wherein the current source circuit includes at least one low-voltage NMOS transistor.

5. The differential circuit of claim 4, wherein the current source circuit is configured to operate in a saturation region in response to a bias voltage applied to a gate of the at least one low-voltage NMOS transistor.

6. The differential circuit of claim 3, wherein the equalizer comprises:
a bandwidth control unit coupled between the source electrodes of the first and second NMOS transistors; and
an equalizer control unit coupled between the source electrodes of the first and second NMOS transistors, and configured to control electrical connection between the source electrodes of the first and second NMOS transistors in response to an equalizer control signal.

7. The differential circuit of claim 6, wherein the bandwidth control unit includes a variable capacitor and a variable resistor that are coupled in parallel with respect to each other, and a capacitance of the variable capacitor and a resistance of the variable resistor are determined in response to a bandwidth control signal.

8. The differential circuit of claim 6, wherein the equalizer control unit comprises a third NMOS transistor having a gate configured to receive the equalizer control signal.

9. The differential circuit of claim 8, wherein the third NMOS transistor is a low-voltage NMOS transistor.

10. The differential circuit of claim 9, wherein the third NMOS transistor is configured to operate in a saturation region in response to the equalizer control signal being applied to the gate of the third NMOS transistor.

11. The differential circuit of claim 3, further comprising a load unit coupled between the high supply voltage and the differential switching circuit.

12. The differential circuit of claim 11, wherein the load unit comprises:
a first load circuit coupled between the high supply voltage and a drain electrode of the first NMOS transistor; and
a second load circuit coupled between the high supply voltage and a drain electrode of the second NMOS transistor.

13. A differential circuit comprising:
a first load coupled to a high power supply voltage;
a second load coupled to the high power supply voltage;
a first NMOS transistor having a high-voltage gate oxide layer, the first NMOS transistor having a gate electrode configured to receive a first input signal and a drain electrode coupled to one terminal of the first load;
a second NMOS transistor having a high-voltage gate oxide layer, the second NMOS transistor having a gate electrode configured to receive a second input signal and a drain electrode coupled to one terminal of the second load, the first and second input signals constituting a differential signal;
an equalizer comprising:
a variable capacitor coupled between source electrodes of the first and second NMOS transistors, and
a variable resistor coupled between the source electrodes of the first and second NMOS transistors and in parallel with the variable capacitor, and
a switching circuit coupled between the source electrodes of the first and second NMOS transistors in parallel with the variable resistor.

14. The differential circuit of claim 13, further comprising a current source coupled between the equalizer and a ground voltage.

15. The differential circuit of claim 14, wherein the differential circuit is employed in a multi-power system and configured to operate at the high power supply voltage and the low power supply voltage.

16. An output buffer circuit in a multi-power system configured to operate at a high power supply voltage and a low power supply voltage, the output buffer circuit comprising:
a pre-driver configured to perform a differential switching operation on first and second differential input signals to output first and second differential output signals;
a blocking capacitor unit including a first blocking capacitor configured to eliminate a DC component of the first differential output signal and a second blocking capacitor configured to eliminate a DC component of the second differential output signal, a first terminal of the first blocking capacitor being coupled to a first output terminal of the pre-driver, a first terminal of the second blocking capacitor being coupled to a second output terminal of the pre-driver;
a voltage reference circuit coupled to a second terminal of the first blocking capacitor and a second terminal of a second blocking capacitor, and configured to shift voltage levels of the DC-eliminated first and second differential output signals; and
a main driver configured to perform a differential switching operation on the DC-eliminated and level-shifted first and second differential output signals to output third and fourth differential output signals, the main driver comprising:
a differential switching circuit including first and second NMOS transistors, and configured to perform a differential switching operation on the DC-eliminated and level-shifted first and second differential output signals to output the third and fourth differential output signals; and
an equalizer coupled between source electrodes of the first and second NMOS transistors, and configured to control a bandwidth of the third and fourth differential output signals.

17. The output buffer of claim 16, wherein the first and second NMOS transistors are a high-voltage NMOS transistor.

18. The output buffer of claim 16, further comprising a current source circuit coupled between the source electrodes of the first and second NMOS transistors.

19. The output buffer of claim 18, wherein the equalizer comprises:
a bandwidth control unit coupled between the source electrodes of the first and second NMOS transistors; and
an equalizer control unit coupled between the source electrodes of the first and second NMOS transistors, and configured to control electrical connection between the source electrodes of the first and second NMOS transistors in response to an equalizer control signal.

20. The output buffer of claim 19, further comprising a load circuit coupled between the high power supply voltage and the differential circuit.

21. The output buffer of claim 16, wherein the pre-driver comprises:
a pre-stage differential switching circuit including third and fourth NMOS transistors, and configured to perform a differential switching operation on the first and second differential input signals to output first and second differential output signals, each of the third and fourth NMOS transistors being a low-voltage NMOS transistor.

22. The output buffer of claim 21, wherein each source electrode of the third and fourth NMOS transistors is coupled at a common source node.

23. The output buffer of claim 22, further comprising a pre-stage current source circuit coupled between the common source node and a ground voltage.

24. The output buffer of claim 23, wherein the pre-stage current source circuit includes at least one NMOS transistor having a low-voltage gate oxide layer.

25. The output buffer of claim 24, wherein the pre-stage current source circuit is configured to operate in a saturation region in response to a bias voltage applied to a gate of the at least one NMOS transistor having the low-voltage gate oxide layer.

26. The output buffer of claim 25, wherein the pre-driver further comprises a pre-stage load unit coupled between the low power supply voltage and the pre-differential switching circuit.

27. The output buffer of claim 26, wherein the pre-stage load unit comprises:
a first pre-stage load circuit coupled between the low power supply voltage and a drain electrode of the third NMOS transistor; and
a second pre-stage load circuit coupled between the low power supply voltage and a drain electrode of the fourth NMOS transistor.
